(19) United States
(12) Patent Application Publication
(10) Pub. No.: US 2011/0186347 A1
(43) Pub. Date: Aug. 4, 2011

(54) SHELL, MANUFACTURING METHOD THEREOF AND ELECTRONIC DEVICE HAVING THE SAME

(76) Inventors: Jiaxin Zhang, Shenzhen (CN); Xiaojia He, Shenzhen (CN); Wenhai Luo, Shenzhen (CN); Yong Ye, Shenzhen (CN); Jinguo Lu, Shenzhen (CN); Guoying Wang, Shenzhen (CN)

(21) Appl. No.: 13/119,415

(22) PCT Filed: Sep. 24, 2009
(86) PCT No.: PCT/CN2009/074191

§ 371 Date: Mar. 16, 2011

(30) Foreign Application Priority Data
Sep. 24, 2008 (CN) 200810216387.9

(51) Int. Cl. H05K 5/03; H05K 13/00; B32B 3/00

(52) U.S. Cl. 174/546; 156/242; 428/195.1

(57) ABSTRACT

A shell for an electronic device is provided. The shell includes a shell body and a pattern layer disposed on an outer surface of the shell body and formed by a curable material. The shell also includes a transparent protective layer disposed on an outer surface of the pattern layer.

The present application claims priority to Chinese patent application No. 200810216387.9, filed on Sep. 24, 2008, the entirety of which is hereby incorporated by reference.

### FIELD OF THE INVENTION

The present invention relates to a shell for an electronic device, a method of manufacturing the shell, and an electronic device having the shell.

### BACKGROUND

Electronic device shells are usually be decorated by printing patterns or forming relief on the surface of the shell. However, the patterns and relief formed by those methods are not fine enough with simple effects, and easy to be frayed with using. Thus the appearance quality of the electronic device can not be assured. With the improvement of the living standard, the individual requirements for electronic device become a main factor besides function and quality. Therefore, it is urgent to develop a new shell for an electronic device to satisfy the individual requirements of consumers.

### SUMMARY OF THE INVENTION

In viewing of the aforesaid, the present invention is directed to solve at least one of the problems existing in the prior art. Accordingly, a shell for an electronic device is provided to meet individualization requirements of consumers. A method of manufacturing the shell thereof and an electronic device having the same are also provided for individualization purpose.

In one aspect, a shell for an electronic device is provided, comprising a shell body; a pattern layer disposed on an outer surface of the shell body and formed by a curable material; and a transparent protective layer disposed on an outer surface of the pattern layer.

In another aspect, a manufacturing method of a shell for an electronic device comprises:

a) providing a mold with a working surface, in which a plurality of cavities are formed in the working surface and used to form a pattern layer on an outer surface of a shell body of the shell;

b) coating a curable material onto the working plane, and covering a transparent protective layer on the curable material;

c) curing the curable material to form the pattern layer, in which the pattern layer and the transparent protective layer are bonded together;

d) taking the bonded pattern layer and transparent protective layer out of the mold and shaping the bonded pattern layer and transparent protective layer to match the outer surface of the shell body of the shell;

e) bonding the shaped and bonded pattern layer and transparent protective layer with the shell body of the shell.

In yet another aspect, an electronic device comprises a body and a shell adapted to the body, in which the shell is manufactured according to the present invention.

According to the present invention, the curable material is cured to form pattern layer so that the patterns are fine and three-dimensional. At the same time, a pattern layer and a transparent protective layer are disposed on the outer surface of shell of the electronic device so that the surface is more wear resistant. Thus, the quality of the electronic device is improved, with improved individualization customization.

Additional aspects and advantages of the embodiments of present invention will be given in part in the following descriptions, become apparent in part from the following descriptions, or be learned from the practice of the embodiments present invention.

### BRIEF DESCRIPTION OF THE FIGURES

These and other aspects and advantages of the invention will become apparent and more readily appreciated from the following descriptions taken in conjunction with the drawings in which:

FIG. 1 is a longitudinal section schematic diagram of the mold used in the present invention;

FIG. 2 and FIG. 3 are longitudinal section schematic views of the product manufactured after the step b according to the embodiment of the present invention;

FIG. 4 and FIG. 5 are longitudinal section schematic views of the product manufactured after the step c according to the embodiment of the present invention;

FIG. 6 is a longitudinal section schematic diagram of the product manufactured after the step d according to the embodiment of the present invention;

FIG. 7 is a longitudinal section schematic diagram of the product manufactured after the step e according to the embodiment of the present invention.

The illustrations of the reference signs in the views are as follows:

M—mold, M1—working plane of the mold, M11—molding cavity of the mold, 1—shell body, 2—pattern layer (or the curable material for forming the pattern layer), 3—transparent protective layer (or the transparent sheet materials for forming the transparent protective layer).

### DETAILED DESCRIPTION OF THE DISCLOSURE

According to the present invention, a shell for an electronic device is provided. As shown in FIG. 7, the shell comprises a shell body 1, a pattern layer 2 on the outer surface of the shell body 1, and a transparent protective layer 3 on the outer surface of the pattern layer 2, in which the pattern layer 2 is formed by a curable material.

The shell body can be made from a substrate of various materials, such as plastic materials selected from the group comprising polyester, polycarbonate (PC), acrylonitrile-butamoldne-styrene (ABS), polymethyl methacrylate (PMMA) and any combination thereof.

The shell body can be manufactured by various methods, such as cutting existing plastic substrates and injection molding directly. The molding method is well known in this art.

The transparent protective layer is formed by transparent sheet materials, the transparent sheet materials can be any kind of wear resistant light transmitting film-forming materials. Since the transparent sheet materials are used as the outermost layer of the shell, in order to improve the wear-resistance, heat-resistance and flexibility of the shell, in some embodiments, the transparent sheet materials are selected from the group comprising polycarbonate, polymethyl methacrylate, polymethyl acrylate, polyethylene glycol terephthalate and any combination thereof. The transmittance of the transparent protective layer is about 80-98%, the thickness of the transparent protective layer is about 0.05-3 μm.

The curable material can be thermosetting materials or light-cured materials. The thermosetting materials include thermosetting resin and so on, such as 902 resin, 898 vinyl ester resin. The light-cured materials include common photosensitive materials (such as TL660) and UV-curable material (such as bisphenol-a epoxy resin acrylate and so on). The curable material is not limited to the above, any curable material can be selected according to concrete conditions, such as silica and so on.

The curable material can be cured to a certain shape to form the pattern layer with the thickness of about 0.01-10 mm. There is a thickness difference between different parts of the pattern layer, in order to prevent the patterns from deforming, the inner surface of the pattern layer is engaged with the outer surface of the shell body.

Some colored materials such as xylin and color paste can be added to the curable material so that the pattern layer is colored. The amount of the colored materials is determined according to the design and based on the weight of the curable material, the addition amount of the colored materials is about 0.01-30% (wt).

The pattern layer can also be colored by disposing a colored layer on the inner surface of the pattern layer. The method for disposing the colored layer can be any technology such as printing and spraying and so on. According to the embodiment of the present invention, the physical vapor deposition (PVD) process is used to forming a metal layer on the inner surface of the pattern layer. In one embodiment, the thickness of the metal layer is about 20-50 nm. The material of the metal layer can be any metal which is suit for physical vapor deposition, such as Ni, Cr, Sn, In, In—Sn alloy, Al, stainless steel and so on. The physical vapor deposition process is widely known in this art, for example, a horizontal coating equipment is used, the cleaning vacuum degree is about 1-5×10⁻² Pa, the cleaning power is about 600 W, the cleaning time is about 20 seconds, the coating vacuum degree is about 2-5×10⁻³ Pa, the coating power is about 3 KW, the coating time is about 2 seconds, and the number of sputtering coating is about 1 time.

According to the present invention, in one embodiment, a binding layer is provided between the colored layer and the shell body in order to protect the colored layer during manufacturing and increase the binding force between the colored layer and the shell body. In one embodiment, the binding layer comprises 1-5 layers of gloss oil and 1-3 layers of adhesive. In another embodiment, the binding layer is formed by 3 layers of bright oil layers and has a thickness of about 5-20 μm. The pattern layer should be baked after every layer is coated, under the condition of about 50-200° C. baking temperature and about 1-360 minutes baking time. In one embodiment the baking temperature is about 80° C. and the baking time is about 30 minutes.

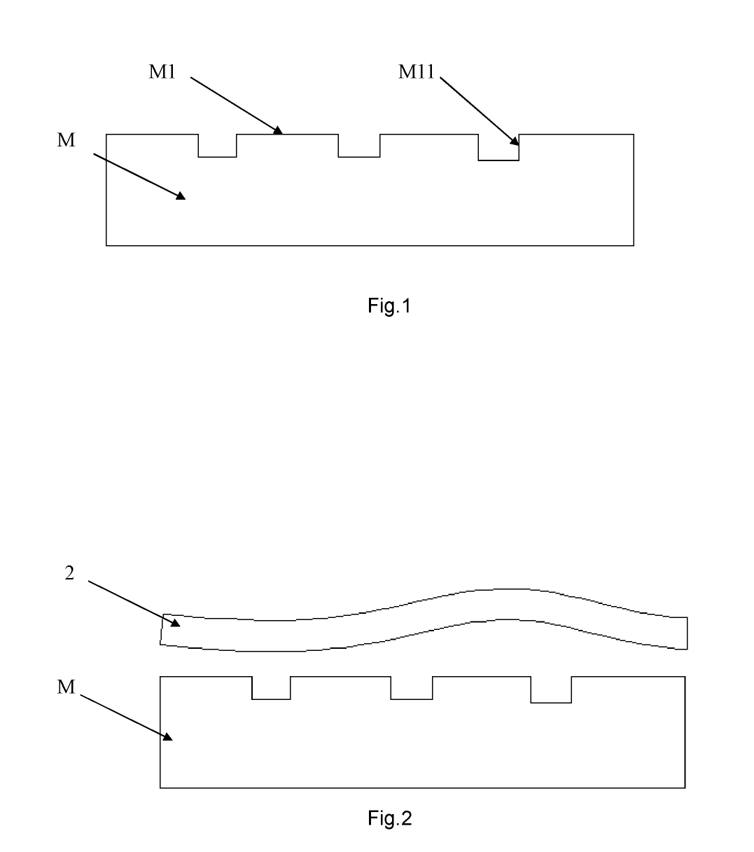

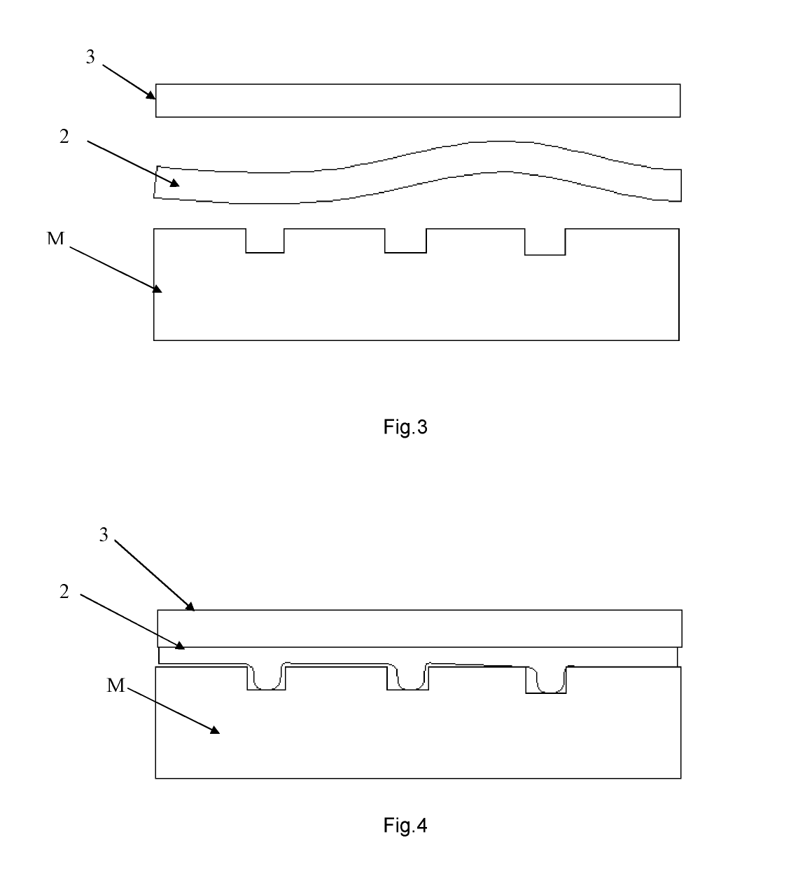

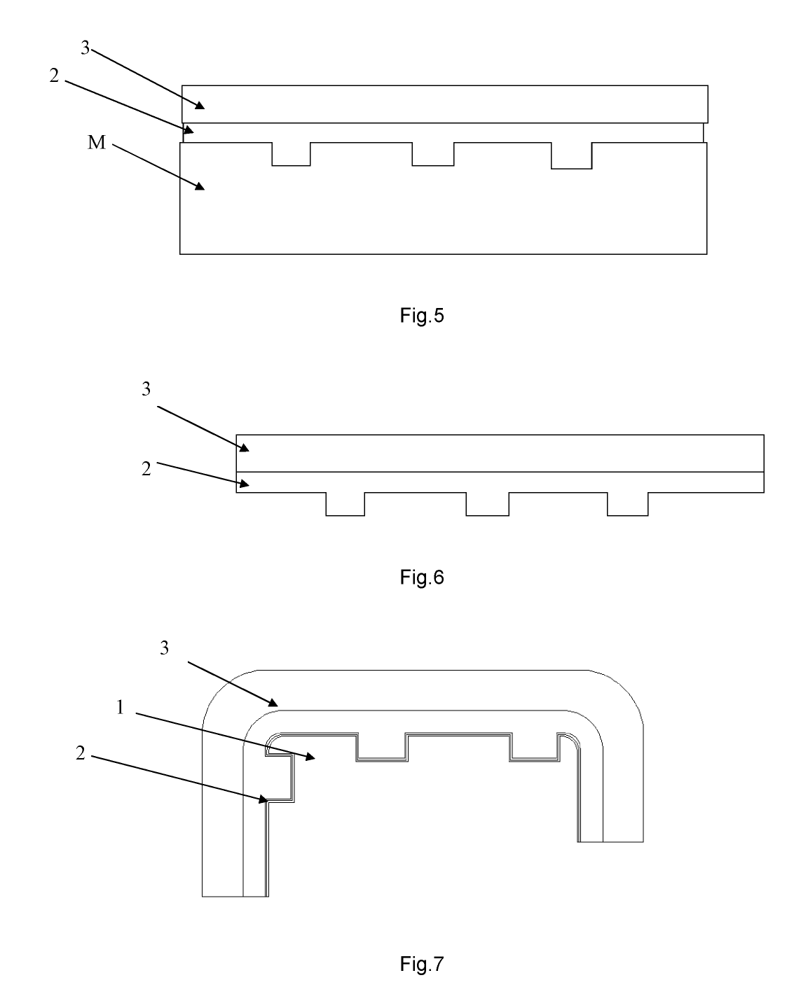

Referring to FIG. 1-FIG. 7, the method of manufacturing the electronic device shell according to the present invention comprises the following steps:

a) providing a mold with a working surface, in which a plurality of cavities are formed in the working surface and used to form a pattern layer on an outer surface of a shell body of the shell;

b) coating a curable material onto the working plane, and covering a transparent protective layer on the curable material;

c) curing the curable material to form the pattern layer, in which the pattern layer and the transparent protective layer are bonded together;

d) taking the bonded pattern layer and transparent protective layer out of the mold and shaping the bonded pattern layer and transparent protective layer to match the outer surface of the shell body of the shell;

e) bonding the shaped and bonded pattern layer and transparent protective layer with the shell body of the shell.

Hereinafter, the method of manufacturing the electronic device shell according to the present invention is illustrated in detail.

Step a) is firstly performed. A mold M with working plane M1 is provided, in which a plurality of cavities M11 are formed in the working plane M1 and used to form the pattern layer on the outer surface of the shell body, and the shape of the cavities M11 corresponds to that of the pattern layer. When designing the mold M, the cavities M11 should be designed based on the patterns on the shell.

Then, a mold block is manufactured by a metal material such as die steel and so on, as shown in FIG. 1. A working plane is formed on the mold block, and a curable material can be coated on the working plane. The working plane can be formed by many kinds of methods, such as wire cutting, milling, precision grinding and so on. In order to get enough smoothness, in one embodiment, the tolerance of the planeness of the working plane is about 0.1 mm, the surface roughness is of at least about B1. In another embodiment the surface roughness is of about A2. The surface roughness international standard (SPI) has four levels: A, B, C, D, and every level further has four sublevels: 0, 1, 2, 3. The B1 level denotes that the surface has no brightness but slight 3000# sand paper stria. The B1 level denotes that the surface has low brightness and no sand paper stria.

In addition, some cavities are formed in the working plane by many kinds of methods, such as machining, chemical etching, electroforming, drilling, stamping and so on. However, in order to obtain finer cavity, in one embodiment the cavities can be manufactured by laser carving the mold block.

The shape of the cavities is corresponding to the patterns of shell. The depth of parts of the cavities can be the same or has a certain depth difference. Then, the pattern layer has even or uneven thickness distribution, and the color changes with the thickness of the parts of the pattern layer.

Step b) is performed after the mold is prepared. The working plane is coated with the curable material, and the shell body is pressed onto and covers the curable material.

Before being cured, the curable material is in a state similar to that of a glue. Therefore, after the curable material is coated onto the working plane, the curable material can flows into and fills the cavities.

In order to facilitate the mould stripping after the curable material is cured, a demolding agent is coated on the working plane before coating the curable material. The demolding agent can be selected from demolding agents of organosilicon such as poly-dimethylsiloxane and methylphenyl silicone oil, but the present invention is not limited hereto, the demolding agent can be any one which can facilitate the stripping of the curable material from the mold.

A transparent sheet is pressed onto and covers the curable material so as to form the transparent protective layer after coating of the curable material is completed.

After the step b) is completed, the curable material is cured, and the transparent sheet is bonded with the curable material. Meantime, the curable material in the cavities is cured to form the patterns. The curing process can be different according to variety of the curable material.

With regard to thermosetting material, the curing process of the thermosetting material in the present invention comprises heating the thermosetting material (e.g. the mold coated with the thermosetting material is placed into a space with high temperature and the thermosetting material is kept at its curing temperature) until the thermosetting material is cured to be solid. The thermosetting material is bonded with the transparent sheet after curing, and projected patterns are formed on the inner surface of the thermosetting materials layer.

With regard to the light-cured material, the curing process is dependent form the light. A UV-curing material is described as an example. After the transparent sheet covers the curing material, the curing material is irradiated with UV. Since the transparent sheet is manufactured by a transparent material, UV can pass through the transparent sheet to the UV-curing material, thus the UV-curing material begins to cure.

The conditions for curing the UV-curing material are follows: the irradiating distance (the distance between the light source and the UV-curing material) is about 1-40 cm, the brightness range is about 200-15,000 mJ/cm², the irradiating time is about 0-200 seconds.

In order to keep the UV-curing material distributed on the working plane has the same curing degree, in one embodiment, a parallel light source is used so that the light intensity radiated onto the working plane is the same.

After the curing material being cured steadily, the curing material is cured to form pattern layer and bonded with the transparent sheet, the patterns are projected patterns whose shape is corresponding to that of the cavities.

After step c) is completed, step d) proceeds. The bonded transparent sheet and pattern layer are taken out of the mold. The even transparent sheet is formed into a shape which is adapted to the shape of the shell body. In one embodiment a high-pressure forming is used, that is, the preheated transparent sheet is molded with application of air-pressure under a temperature higher than about 150° C. on a metal mold. In the molding process, the molding temperature, the pressure and the pressure maintaining time should be adjusted well. For example, in this embodiment, a high pressure molding machine of is used, the molding temperature is about 380° C., the baking time is about 7 seconds, the high pressure is about 41 Kg and maintained for about 6 seconds, then, the low pressure of about 7 Kg is applied and maintained for about 5 seconds, and it takes about 12 seconds to discharge gas finally. After the high pressure molding step, the material on the transparent sheet which need not to be bonded with the shell body is punched away, then the product which is formed by molded-bonded transparent protective layer and patterns is obtained, as shown in FIG. 6.

The product obtained in step d) is bonded with the electronic device shell body. According to the embodiment of the present invention, the bonding method is injection molding, during which the resin which is used to form the shell body and the transparent protective layer are molded together. Before the injection molding, the transparent protective layer is inserted into the injection mold from back. The injection mold includes a female mold and forming mold (male mold), the depth of the cavity of the female mold shall be larger than the height of the forming mold by the thickness of the transparent protective layer. After the transparent protective layer is placed into the female mold, the resin which is used to form the shell body is injected on the inner surface of the transparent protective layer so that the resin is bonded with the transparent protective layer. In this embodiment, the plastic material is PC3700, the injection molding temperature is about 260-275° C. The injection molding method is well known in this art.

According to the present invention, an electronic device is provided. The electronic device comprises a body and a shell connected to the body. The shell is manufactured according to the method of the present invention. The body comprises all elements contained in the shell which can realize the functions of the electronic device. The species, combination and connection relation of the elements are well known in this art.

There is no limit to the electronic device provided according to the present invention, the electronic device can be a mobile phone, MP3, PDA, a notebook, a digital camera and so on. In one embodiment, the electronic is a mobile phone.

Although explanatory embodiments have been shown and described, it would be appreciated by those skilled in the art that changes, alternatives, and modifications can be made in the embodiments without departing from spirit and principles of the invention. Such changes, alternatives, and modifications all fall into the scope of the claims and their equivalents.

1. A shell for an electronic device, comprising:
a shell body;
a pattern layer disposed on an outer surface of the shell body and formed by a curable material; and
a transparent protective layer disposed on an outer surface of the pattern layer.

2. The shell according to claim 1, wherein at least one colored material is added to the curable material.

3. The shell according to claim 1, wherein the curable material is a light-curable material or a thermosetting material.

4. The shell according to claim 1, wherein the pattern layer has a thickness of about 0.01-10 mm.

5. The shell according to claim 1, wherein the outer surface of the shell body is engaged with an inner surface of the pattern layer.

6. The shell according to claim 1, wherein the transparent protective layer is formed by a material selected from a group comprising polycarbonate, polymethyl methacrylate, polyethylene terephthalate, and any combination thereof, and the transparent protective layer has a transmittance of about 80-98% and a thickness of about 0.05-3 μm.

7. The shell according to claim 1, wherein the shell further comprises a colored layer disposed between the pattern layer and the transparent protective layer.

8. The shell according to claim 7, wherein the colored layer is of metallic color and has a thickness of about 20-50 nm.

9. The shell according to claim 7, wherein the shell further comprises a binding layer attached to an inner surface of the colored layer and having a thickness of about 5-20 μm.

10. The shell according to claim 9, wherein the binding layer comprises at least one gloss oil layer.

11. A manufacturing method of a shell for an electronic device, comprising steps of:
a) providing a mold with a working plane, in which a plurality of cavities are formed in the working surface and used to form a pattern layer on an outer surface of a shell body of the shell;
b) coating a curable material onto the working plane, and covering a transparent protective layer on the curable material;
c) curing the curable material to form the pattern layer, wherein the pattern layer and the transparent protective layer are bonded together;
d) taking the bonded pattern layer and transparent protective layer out of the mold and forming the bonded pattern layer and transparent protective layer into a shape which matches the outer surface of the shell body of the shell;
e) bonding the shaped and bonded pattern layer and transparent protective layer with the shell body of the shell.

12. The method according to claim 11, wherein the working plane has a roughness level of about SPIB I-SPIA2.

13. The method according to claim 11, wherein the bonded pattern layer and transparent protective layer are bonded with the shell body by means of injection molding.

14. The method according to claim 13, wherein the outer surface of the shell body is engaged with the inner surface of the pattern layer.

15. An electronic device, comprising a body, and a shell which is adapted to the body and set forth in claim 1.

16. The shell according to claim 2, wherein the curable material is a light-curable material or a thermosetting material.

17. A shell for an electronic device, comprising:
a shell body;
a pattern layer disposed on an outer surface of the shell body and formed by a curable material; and
a transparent protective layer disposed on an outer surface of the pattern layer,
wherein the outer surface of the shell body is engaged with an inner surface of the pattern layer, and
wherein the shell further comprises a colored layer disposed between the pattern layer and the transparent protective layer.

18. The shell according to claim 17, wherein the shell further comprises a binding layer attached to an inner surface of the colored layer and having a thickness of about 5-20 μm.

19. The shell according to claim 17, wherein the colored layer is of metallic color and has a thickness of about 20-50 nm.

20. The shell according to claim 17, wherein the pattern layer has a thickness of about 0.01-10 mm.
